(19) United States
(12) Patent Application Publication
(10) Pub. No.: US 2011/0101502 A1
(43) Pub. Date: May 5, 2011

(54) COMPOSITE WAFERS AND SUBSTRATES FOR III-NITRIDE EPITAXY AND DEVICES AND METHODS THEREFOR

(75) Inventor: Shaoping Wang, Brookfield, CT (US)

(73) Assignee: Fairfield Crystal Technology, LLC, New Milford, CT (US)

(21) Appl. No.: 12/917,587

(22) Filed: Nov. 2, 2010

Related U.S. Application Data
(60) Provisional application No. 61/258,270, filed on Nov. 5, 2009.

(51) Int. Cl. H01L 29/38

(52) U.S. Cl. 257/615; 257/E29.105

(57) ABSTRACT

A composite wafer comprises a single crystal substrate having first and second sides; a first III-nitride single crystal layer disposed on the first side of the substrate and being defined by a thickness; and a second III-nitride single crystal layer disposed on the second side of the single crystal substrate and being defined by a thickness. The thickness of each III-nitride single crystal layer is substantially the same. The composite wafer may be used in the manufacture of a semiconductor device or a freestanding wafer.

### CROSS REFERENCE TO RELATED APPLICATION(S)

This application claims the benefit of U.S. provisional application No. 61/258,270, filed Nov. 5, 2009, the contents of which are incorporated herein by reference in their entirety.

### U.S. GOVERNMENT RIGHTS

N.A.

### BACKGROUND OF THE INVENTION

III-nitride semiconductive materials (e.g. GaN, AlN, InN, InGaN, AlGaN, and InAlGaN) are employed in the fabrication of a variety of semiconductor devices, such as blue, green, UV, and white light emitting diodes (LEDs), blue and green laser diodes (LDs), high frequency devices (e.g. high electron mobility transistors, also known as HEMTs), high-power switching devices, UV detectors, photovoltaic devices (solar cells), etc. In particular, III-nitride-based LEDs have possible desirable utility in general illumination applications because of their likely energy savings potential, long lifetime, compactness, and high efficiency. However, despite the progress made in recent years in efficacies of commercial III-nitride-based blue, green, and white LEDs, LED lighting products in illumination applications still fall short of suitable performance and price requirements needed to meet market demands.

III-nitride-based LEDs emitting blue, green, UV, and white light are usually produced with III-nitride thin films grown on a substrate. To date, native III-nitride substrates (GaN and AlN) are either not commercially available in large sizes and/or are too costly to be considered as a viable choice of substrates for commercial volume production of LEDs. Commercial III-V nitride-based LEDs are currently fabricated from III-nitride thin films grown heteroepitaxially on sapphire substrates (which accounts for about 90% of world III-nitride LEDs produced at the moment) and SiC substrates using a metal-organic chemical vapor deposition (MOCVD) technique (also known as metal organic vapor phase epitaxy (MOVPE) technique). Other commercially available substrates, such as Si, GaAs, ZnO, other oxides (e.g. LiAlO₃) may be used for III-nitride epitaxy and device fabrication.

GaN and III-nitride LEDs made on sapphire substrates usually consist of an undoped GaN layer, an n-type GaN layer, a multi-quantum-well (MQW) layer, and a p-type GaN layer (about 3 μm in total thickness). At present, the highest efficacy demonstrated in packaged commercial white-light LEDs grown on sapphire substrates (and SiC substrates) is about 100 lumens/watt (w) for “cool white” and 60 lumens/w for “warm white,” which is much lower than the practical limit for white LED efficacies (about 230 lumens/w for “cool white” and 160 lumens/w for “warm white.”) Furthermore, the high cost of producing GaN-based LEDs typically hinders a wide adoption of LEDs in general lighting applications.

Commercial III-V nitride-based LEDs are currently fabricated from III-nitride thin films grown heteroepitaxially on sapphire substrates or SiC substrates. Since the incumbent sapphire substrates currently account for more than 90% of III-nitride high-brightness LEDs produced, improving or replacing sapphire substrates with more desirable substrates for fabrication of III-nitride LEDs can enhance LED performance and reduce production cost of high-brightness LEDs. Despite their low cost and wide commercial availability, the incumbent sapphire substrates have drawbacks that limit the ability of commercial III-nitride LED manufacturers to achieve higher yield, lower cost, and better device performance. Two prominent such drawbacks of sapphire substrates are: (a) large thermal expansion mismatches between sapphire and GaN leading to a large bow in the wafers containing LED device structures, and (b) large crystal lattice mismatch between sapphire and GaN leading to high dislocation densities in GaN and III-nitride thin films. These two issues will be discussed in more detail as follows:

### Thermal Expansion Mismatch

Sapphire generally has a coefficient of thermal expansion (CTE) much larger than that of GaN (as well as other III-nitrides, such as AlN, InGaN and AlGaN). As a result, a sapphire substrate with III-nitride LED layers grown on it at a high temperature (e.g., 1000-1100° C.) will have a significant bow when the substrate is cooled down to room temperature due to CTE mismatch. The wafer bow complicates the subsequent LED device fabrication and test processes. In fact, as the substrate size gets larger (e.g., 4 inches, 6 inches, 8 inches, etc.), the mechanical bow due to CTE mismatch between sapphire and GaN can get intolerably large for photolithography and other device fabrication steps. The mechanical bow is one issue resulting in difficulties of implementing large diameter substrates in commercial LED production. Consequently, without being able to scale up the LED manufacture process to adopt progressively larger substrates (e.g., 6-inch, 8-inch, etc.), the cost of III-nitride LEDs will remain too high for general illumination applications. Scaling-up the fabrication processes for other III-nitride devices by using progressive larger diameter substrates is also desirable for the reduction of production cost of these III-nitride devices.

### Lattice Mismatch

Sapphire has a crystal lattice mismatch to GaN at about 13.8%. This lattice mismatch leads to a high dislocation density, usually in the range of 10¹⁰-10⁹ cm⁻², in GaN thin films (usually about 3 μm in total thickness) grown on sapphire substrates using an MOCVD technique. MOCVD techniques (or MOVPE techniques) are commonly employed for growing LED device layers. The growth rates in an MOCVD process for GaN and other III-nitrides are usually a few micrometers per hour or less. Growth of a thicker GaN layer, e.g. 5-10 μm in total thickness, does not significantly decrease dislocation densities in GaN layers but significantly increases wafer bow arising from the large CTE mismatch between sapphire and GaN, which also significantly reduces throughput of the MOCVD epitaxy process. Dislocation densities in MOCVD-grown GaN thin films may be reduced to 10⁸ cm⁻² or even lower through several means, such as, a lateral epitaxial overgrowth (LEO) technique, a selected area growth (SAG) technique, and a pendeo-epitaxy (PE) technique. These techniques, however, are costly to implement. In addition, as the diameter of a substrate becomes larger, it becomes more difficult to implement an LEO, an SAG, or a PE process. This is partly due to wafer bows induced by CTE mismatch. Furthermore, implementation of an LEO or an SAG process in MOCVD growth of III-nitride LED layers adds more cost to commercial high brightness LEDs (HB-LEDs) produced.

Another growth technique, know as hydride vapor phase epitaxy (HVPE), has been used to grow GaN thick films (e.g. 5-1000 μm) on sapphire or other substrates. An HVPE growth is capable of producing high-quality GaN single crystal thick films as well as other III-nitrides at a high growth rate between 10-100 μm/hr. HVPE-grown GaN thick films, on a substrate or in a freestanding form, have exhibited dislocation densities on the order of or less than 10⁷ cm⁻², and even less than 10⁶ cm⁻². The HVPE technique has been used to produce two different types of GaN wafers: (a) a GaN template—a wafer comprised of a GaN layer (usually 2-20 μm in thickness) grown on one side of a sapphire substrate or a SiC substrate, and (b) a freestanding GaN wafer with the substrate completely removed. Unlike the extremely small surface roughness (e.g., a root mean square (RMS) roughness of less than 0.5 nm in a 20×20 μm atomic force microscope (AFM) scan) achievable in MOCVD-grown GaN thin films on sapphire substrates, as-grown HVPE GaN films usually have much larger surface roughness values (usually higher than 3 nm RMS). Thicker HVPE-GaN films result in larger surface roughness values. Therefore, an HVPE-grown GaN template layer (as well as an HVPE-grown freestanding GaN wafers) is polished to achieve an epi-ready surface roughness (e.g. <0.5 nm RMS roughness) for use as a substrate for GaN MOCVD growth of III-nitride device layers. Also, because of the large wafer bow in a GaN/sapphire template due to CTE mismatch, polishing a GaN template is technically challenging and economically costly. Therefore, freestanding GaN wafers produced currently using HVPE techniques are generally prohibitively expensive for use as substrates for fabrication of LEDs.

### SUMMARY

The details of one or more embodiments of the invention are set forth in the accompanying drawings and the description below. Other features, objects, and advantages of the invention will be apparent from the description and drawings, and from the claims.

In one aspect, the present invention resides in a composite wafer comprising a single crystal substrate having a first side and an opposing second side; a first III-nitride single crystal layer disposed on the first side of the single crystal substrate and being defined by a thickness; and a second III-nitride single crystal layer disposed on the second side of the single crystal substrate and being defined by a thickness. The thickness of the first III-nitride single crystal layer is substantially the same as the thickness of the second III-nitride single crystal layer.

In another aspect, the present invention resides in an LED comprising a multi-quantum well layer having a first side and an opposing second side; a first III-nitride single crystal layer disposed on the first side of the multi-quantum well layer; a second III-nitride single crystal layer disposed on the second side of the multi-quantum well layer; a first electrode disposed on the first III-nitride single crystal layer; and a second electrode disposed on the second III-nitride single crystal layer.

In another aspect, the present invention resides in a freestanding wafer comprising a III-nitride single crystal layer produced by a process of depositing a film by hydride vapor phase epitaxy on a substrate and subsequently removing the substrate.

In another aspect, the present invention resides in a method of producing an LED layer. This method comprises the steps of providing a double-sided composite wafer; depositing a GaN epi-layer on the double-sided composite wafer; depositing an LED layer comprising a first layer of an n-type material, a multi-quantum well layer, and a layer of a p-type material on the GaN epi-layer; and removing at least a portion of the double-sided composite wafer. The double-sided composite wafer comprises a single crystal substrate having a first side and an opposing second side and a III-nitride single crystal layer disposed on the first side of the single crystal substrate and being defined by a thickness.

### BRIEF DESCRIPTION OF THE DRAWINGS

FIG. 1A is a schematic representation of a DS GaN composite wafer.

FIG. 1B is a schematic representation of a GaN/sapphire template having a mechanical bow.

FIG. 2 is a schematic representation of another DS composite wafer.

FIG. 3 is a schematic representation of another DS composite wafer.

FIG. 4 is a schematic representation showing the distortion height in a substrate with a bow.

FIG. 5 is a schematic representation of a cross section of an HVPE growth chamber.

FIG. 6A is a schematic representation of a process for making a DS GaN composite substrate for use in making LEDs.

FIG. 6B is a schematic representation of a vertical LED device made from a DS composite wafer.

Like reference numbers and designations in the various drawings indicate like elements.

### DETAILED DESCRIPTION

The present invention discloses a composite wafer made of a III-nitride layer on one side of a single crystal substrate (e.g., a sapphire substrate) and a separate III-nitride layer on the other side of the same substrate in such way that the thickness of the two III-nitride layers on the opposing sides of the substrate is approximately the same. Such a composite wafer is referred to as a DS (double-sided) composite wafer. The thickness of one of the III-nitride layers on a substrate may range from 1 μm to 1000 μm, more preferably from 5 μm to 500 μm.

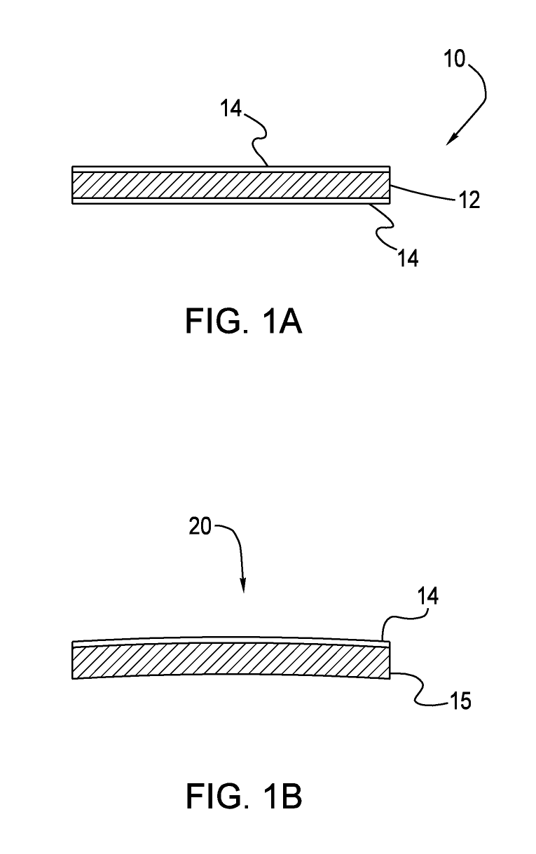

Referring to FIG. 1A, one example of a DS composite wafer is shown generally at 10 and is hereinafter referred to as “wafer 10.” Wafer 10 comprises a sapphire substrate 12 having opposing upper and lower sides on which crystal layers shown at 14 are respectively disposed. In wafer 10, the crystal layers 14 are GaN single crystal layers, which thereby define the wafer by a GaN/sapphire/GaN configuration. Referring also to FIG. 1B, a GaN/sapphire template 20 is depicted for comparison with the wafer 10 as shown in FIG. 1A to illustrate potential differences in mechanical features such as mechanical distortion. The present invention is not limited to the use of GaN in the crystal layers 14, as shown in FIG. 1A, as other materials may be used to produce variations of the III-nitride DS composite wafers (described below). It should also be realized that a GaN/sapphire/GaN composite wafer (wafer 10) may have a small or essentially no discernible mechanical distortion in the form of bow and warp (contrary to the template 20 of FIG. 1B) due to the mechanical stresses resulting from CTE mismatch associated with the two opposing GaN layers of approximately the same thickness being nearly or completely cancelled out. The GaN/sapphire template 20, as shown in FIG. 1B, is defined by a substrate 15 having a discernible mechanical bow, making it essentially in a shape of a concave/convex lens, with the sapphire face without the GaN film on the concave surface and the sapphire face with the GaN film as the crystal layer 14 on the convex surface, as schematically depicted in FIG. 1B.

Variations of III-nitride DS composite wafers with respect to the material types and the layer sequence of stacking are represented by a short-hand notation as illustrated in FIGS. 1A, 2, and 3.

Examples of some variations of a DS composite wafer according to this invention are given in the short-hand notation as follows:

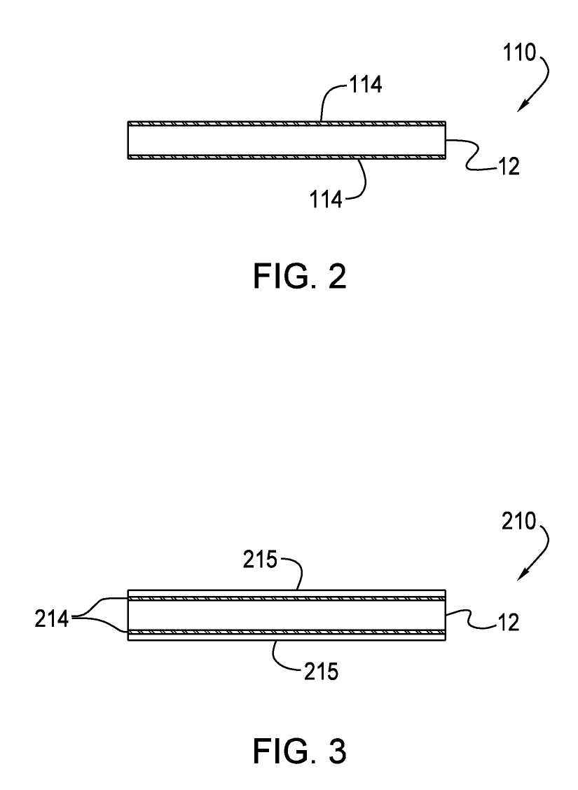

I. A single-layer DS composite wafer: (a) GaN/Sapphire/GaN (shown at 10 in FIG. 1A), (b) AlN/Sapphire/AlN (shown at 110 in FIG. 2, which depicts AlN crystal layers 114 on the sapphire substrate 12), (c) InN/Sapphire/InN, (d) AlGaN/Sapphire/AlGaN, (e) InGaN/Sapphire/InGaN, (f) InAlN/Sapphire/InAlN, (g) InGaAlN/Sapphire/InGaAlN. This may be generally denoted as: InₓGa_{y}Al_{1-x-y}N/Sapphire/InₓGa_{y}Al_{1-x-y}N, where, 0≦x≦1, and 0≦y≦1.

II. A double-layer DS composite wafer: (a) AlN/GaN/Sapphire/GaN/AlN, (b)

GaN/AlN/Sapphire/AlN/GaN (shown at 210 in FIG. 3, which depicts AlN crystal layers 214 on the sapphire substrate 12 and GaN thin film layers 215 disposed over the AlN crystal layers 214), (c) InN/GaN/Sapphire/GaN/InN, (d) InN/AlN/Sapphire/AlN/InN, (e) InGaN/GaN/Sapphire/GaN/InGaN, (f) AlGaN/AlN/Sapphire/AlN/AlGaN, (g) AlGaN/GaN/Sapphire/GaN/AlGaN, (h) InGaAlN/GaN/Sapphire/GaN/InGaAlN, (i) InGaAlN/AlN/Sapphire/AlN/InGaAlN.

III. A triple-layer DS composite wafer: (a) InN/AlN/GaN/Sapphire/GaN/AlN/InN, (b) AlN/GaN/AlN/Sapphire/AlN/GaN/AlN, (c) InGaN/GaN/AlN/Sapphire/AlN/GaN/InGaN, (d) AlGaN/AlN/GaN/Sapphire/GaN/AlN/AlGaN, (e) InGaAlN/AlN/GaN/Sapphire/GaN/AlN/InGaAlN, (f) InGaAlN/GaN/AlN/Sapphire/AlN/GaN/InGaAlN.

The present invention is not limited with regard to the above variations, as other variations are possible for a III-nitride DS composite wafer. Furthermore, it should be pointed out that the sapphire substrate in a DS composite wafer can be replaced by other substrate materials, such as GaAs, SiC, Si, Ge, ZnO, LiAlO₃, etc.

There are three attributes of a DS composite wafer disclosed in the current invention: (a) A low mechanical bow regardless of wafer diameter, (b) A low dislocation density, and (c) The ability to enable fabrication of vertical devices. The term “low” as used herein means that property being described is within an acceptable range or less than a selected desired threshold value. These attributes are explained in more details as follows:

A low mechanical bow can be achieved in a DS composite wafer such as wafer 10. With regard to achieving a low mechanical bow, two aspects are taken into consideration. In the first aspect, a DS composite substrate is inherently non-polar because a sapphire single crystal has a non-polar crystal structure, i.e. the two surfaces of a double-side-polished sapphire substrate of any crystal orientation, including the (0001) orientation commonly used in fabrication of III-nitride LEDs, have a substantially identical crystallographic structure. As a result, the two GaN layers grown on a sapphire substrate, i.e. one layer on each of the two surfaces of a double-side-polished sapphire substrate, can have approximately the same mechanical and electrical properties as well as the same crystalline quality. This results in a low amount of mechanical bow or no mechanical bow at all in a DS composite wafer using a sapphire substrate as the base substrate. A low bow in a composite wafer may also be achieved on substrates with polar surfaces, e.g., SiC (0001) and GaAs (111), or semi-polar surfaces, e.g., SiC (11-21). The two GaN layers grown on each side of a polar substrate may differ somewhat in terms of their mechanical properties and crystalline quality, as well as their electrical properties.

With regard to the second aspect, a DS composite wafer is also able to maintain a low mechanical bow when the composite wafer is used as a substrate in a MOCVD epitaxy growth of III-nitride thin films for devices. This point may be illustrated using the following example involving an epitaxy growth of III-nitride layers for LEDs. In the prior art, an MOCVD epitaxy growth run for III-nitride LED layers consists of two steps:

Step 1—Grow a GaN thin film (including an ultra-thin, e.g., 50 nm thick, low-temperature buffer layer made of AlN or GaN) with a thickness on the order of 2-3 μm on a sapphire substrate, the purpose of this GaN layer being to provide a GaN template layer with an acceptable dislocation density (e.g., on the order of 10⁹ cm⁻²);

Step 2—Grow a LED structure on top of the GaN template layer created in Step 1, i.e. an n-type GaN layer (about 0.2 μm in thickness), an InGaN/GaN multi-quantum-well (MQW) layer (<0.1 μm in total layer thickness), and a p-type GaN layer (about 0.2 μm in thickness).

However, if an epi-ready GaN substrate is used in place of the sapphire substrate, Step 1 can be dramatically shortened or even omitted altogether. Since a MOCVD production tool for III-nitride epitaxy is designed for growth of very thin III-nitride LED active layers, such as MQW structures (of about several tenths of a nanometer in thickness) with an extremely high precision, omission of Step 1, i.e. the growth of a GaN template layer of 2-3 μm in thickness, can dramatically increase throughput of the epitaxy process and reduce production cost of LEDs.

GaN templates made of a GaN layer grown on only one side of a sapphire substrate (or a SiC substrate) using an HVPE technique are intended to replace the incumbent sapphire substrates for LED production. However, GaN templates fail to address the following three issues: (a) a large mechanical bow in a GaN template due to CTE mismatch poses problems for epitaxy and device fabrication, (b) a large surface roughness (usually larger than 3 nm RMS) inherent of an HVPE-growth GaN thick film on a sapphire or SiC substrate results in inferior GaN/InGaN LED layers (and polishing a GaN template with a mechanical bow is challenging and costly), and (c) a dislocation density either comparable to or only moderately lower than that in a MOCVD-grown GaN thin film produced in Step 1 in a regular epitaxy process for LED layers. Therefore, using a regular GaN template wafer in LED manufacture provides no gains in terms of epi-layer quality, device performance, and LED cost reduction.

By using a DS composite wafer (wafer 10) disclosed in this invention as a substrate for MOCVD epitaxy of III-nitride LED layers, Step 1 in the MOCVD epitaxy of GaN thin film of about 2-3 μm in thickness is replaced with a growth of a thin GaN epi-layer of about 0.1 μm in thickness followed by Step 2—growth of an LED structure (i.e. an n-type GaN layer, a GaN/InGaN MQW layer, and a p-type GaN layer). The total thickness of all the MOCVD LED layers grown in Step 1 and Step 2 when using a DS composite wafer as a substrate can be as small as about 0.5 μm. For a DS composite wafer with a GaN layer of 5 μm in thickness on each side of a sapphire substrate, an additional GaN/InGaN MQW layer of about 0.5 μm in total thickness would result in a very small bow in the LED wafer produced. For a DS composite wafer with a GaN layer of 10 μm in thickness on each side of a sapphire substrate, an additional GaN/InGaN MQW layer of about 0.5 μm in thickness would result in an even smaller bow in the LED wafer. In another example, for a DS composite wafer with a GaN layer of 50 μm in thickness on both sides of a sapphire substrate, an additional GaN/InGaN MQW layer of about 0.5 μm in thickness would result in essentially no bow in the LED wafer, as the difference between the stresses due to CTE mismatch is insignificant. In fact, for the same total thickness of LED layers (i.e. an n-type GaN, a MQW layer, and a p-type layer), the thicker the GaN layers in a DS composite substrate are, the smaller the bow in the resulting LED wafer is. The low wafer bow resulting from using a DS composite wafer in a MOCVD growth of LED layers greatly simplifies the device manufacture process (e.g., the front-end and the back-end device processing) for making LED dies, which leads to a lower cost of LED manufacture. When Step 1 (i.e. the GaN template layer growth) in an MOCVD epitaxy run is omitted when using a DS composite wafer as a substrate, the throughput of the MOCVD epitaxy process is also greatly increased because of a shortened epitaxy growth, which leads to a significant cost reduction in LED manufacture.

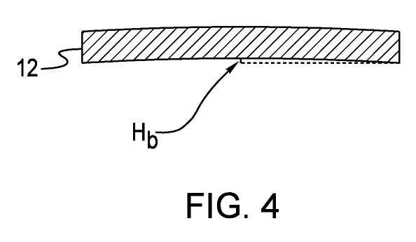

Wafer bows can be quantified using the distortion height of a wafer, H_{b}, as shown schematically in FIG. 4. The H_{b} value of a substrate 12 determines whether a wafer made using the substrate 12 is adequate to be used in a photolithography process in device fabrication. For LED fabrication, a wafer with an H_{b} value not exceeding about 0.1 mm is desirable for use with a lithographic tool for patterning devices. A DS composite wafer of any diameter (e.g., 4 inches, 8 inches, 12 inches, etc.) should be capable of maintaining a low mechanical bow (e.g., less than about 0.2 mm), which facilitates the scale-up to use substrates of progressively larger diameter wafers in LED manufacture as compared to using regular sapphire substrates. Therefore, a DS composite wafer will be a preferred substrate for volume production of LEDs.

With regard to the second attribute, a DS composite wafer has a low dislocation density. For example, a DS GaN composite wafer having a sapphire substrate (such as wafer 10) may have a dislocation density in the range of 1×10⁸ cm⁻² to 1×10⁶ cm⁻², which is considerably lower than dislocation densities (e.g. 5×10⁸ cm⁻² or higher) in MOCVD-grown GaN thin films from a current the-state-of-art LED production process. A DS composite wafer, such as wafer 10, may be produced using a MOCVD technique or an HVPE technique or a combination of the two techniques. Details about dislocation densities in a DS composite wafer produced by a MOCVD technique or an HVPE technique may be explained, as follows, using the wafer 10 as an example:

When a MOCVD technique is used for growth of the wafer 10, the thickness of a crystal layer 14 on each surface of a sapphire substrate 12 may be in the range of 1-25 μm, more preferably in the range of 3-15 μm. Where the crystal layers 14 are GaN, thicker GaN layers in a DS composite wafer are possible but not economical. This is because growth rates for GaN single crystal films in an MOCVD technique are low, typically in the range of 1-3 μm/hr. However, an MOCVD technique produces a GaN thin film on a sapphire substrate with a low surface roughness (e.g. less than 0.5 nm RMS). Therefore, a MOCVD-grown DS GaN composite wafer would have an epi-ready as-grown surface without being further polished. Because of the low bow in a DS GaN composite wafer (e.g., wafer 10), the techniques for reducing defect densities in GaN layers, such as lateral epitaxial overgrowth (LEO) techniques, selected area growth (SAG) techniques, and pendeo-epitaxy (PE) techniques, can be implemented straightforwardly, which can yield GaN layers in a DS composite wafer with a low dislocation density in the range from 1×10⁸ cm⁻² to 1×10⁶ cm⁻². A DS GaN composite wafer with a dislocation density with an epi-ready as-grown surface is suitable for use as a substrate for volume production of LEDs and other III-nitride-based devices. One way to produce a DS GaN composite wafer (such as wafer 10) using an MOCVD technique is to grow one GaN layer on one side of a double-side polished sapphire substrate 12 and then grow one GaN layer of a similar thickness on the other side of the same sapphire substrate. Such a technique can be termed “single-side growth.” Another way is to grow a GaN layer simultaneously on both sides of a sapphire substrate—a “double-side growth.” A “single-side growth” can be achieved using an MOCVD tool used for epitaxy growth of III-nitride LEDs. Examples are MOCVD tools made by AIXTRON, VEECO, THOMAS SWAN, etc. Lower cost dedicated MOCVD tools can also be built for growth of DS GaN composite wafers to reduce production cost considerably. For a “double-side growth,” there is no known MOCVD tools available. In addition, it should also be pointed out that, in both the “single-side growth” and the “double-side growth” approaches, a GaN layer with a III-nitride LED structure may be grown during the same run for a DS GaN composite substrate, which can considerably reduce the cost for LED production.

When an HVPE is used for producing a DS GaN composite wafer such as wafer 10, on the other hand, the thickness of a GaN layer on each surface of the sapphire substrate 12 may be in the range of 10-1000 μm, more preferably in the range of 20-500 μm. An HVPE technique is well suited for growing thick GaN layers because of the high growth rate achievable (e.g., 10-100 μm/hr). It was found that, in HVPE-grown GaN thick film sapphire, the thicker the GaN films are, the dislocation densities in the GaN become lower. Typically, dislocation densities in HVPE-grown GaN thick films up to 1 mm in thickness are in the range of 10⁸-10⁷ cm⁻². GaN thick films with such low dislocation densities are desirable for use as substrates for fabricating high-performance LEDs. A DS GaN composite wafer (wafer 10) with a GaN thick film on each side of the sapphire substrate 12 can also maintain a low wafer bow. Because of the low bow in a DS GaN composite wafer, the techniques for further reducing defect densities in GaN layers, such as, a lateral epitaxial overgrowth (LEO) technique or a selected area growth (SAG) technique, can also be implemented during an HVPE growth, which can yield GaN layers in a DS composite wafer with a low dislocation density on the order of 10⁶ cm⁻². GaN thick films with dislocation densities on the order of 10⁶ cm⁻² are desirable for use as substrates for fabrication of laser diodes. However, the surface roughness of as-grown GaN layers in an HVPE-grown DS GaN composite wafer, regardless the thickness of the layers, is generally too large to be epi-ready for epitaxy of III-nitride LED structures. The GaN layers are mechanically polished and followed by a chemo-mechanical polishing (CMP) or a reactive ion etching (RIE) process to achieve an epi-ready surface finish (e.g., a surface roughness less than 0.5 nm RMS). Because of the low wafer bow, polishing DS GaN composite wafers into epi-ready substrates is as straightforward as polishing sapphire wafers into epi-ready substrates.

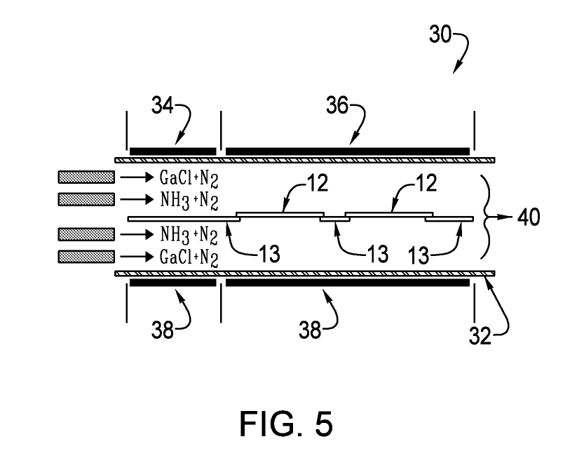

When producing a DS GaN composite wafer using an HVPE technique, a GaN layer can be grown simultaneously on both sides of the sapphire substrate 12, i.e. via a “double-sided growth,” so that the DS composite wafer with thick GaN layers will maintain a low bow throughout the growth process. Referring now to FIG. 5, a portion of an HVPE growth chamber is designated generally by the reference number 30 and is referred to as chamber 30. Chamber 30 is defined at least in part by a quartz enclosure 32 that receives precursors, carrier gases, and/or other materials into a mix zone 34 of the quartz enclosure and directs such materials to a growth zone 36 for deposition onto the substrates 12. The substrates 12 are supported on wafer supports 13. In supporting the substrates on wafer supports 13, a “double-sided growth” is effected on the substrates 12. Heaters 38 are disposed in one or more of the mix zone 34 and the growth zone 36. Excess materials (precursors, carrier gases, and the like) are removed from the chamber 30 via an exhaust 40.

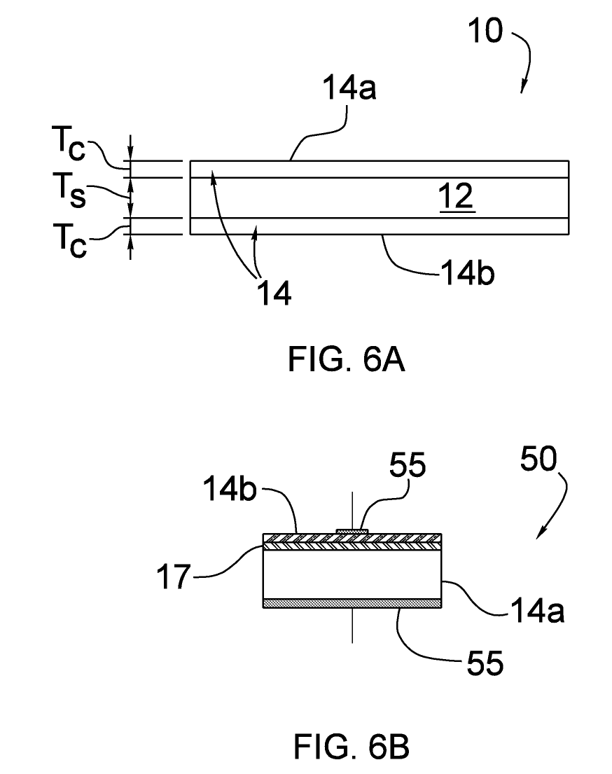

The third attribute of a DS composite wafer relates to the ability of the wafer to enable fabrication of vertical devices. Currently in commercial LED manufacture, there are two LED structures in terms of where the two electrical contacts are placed: (a) the two electrodes are on the same side of an LED die, or (b) the two electrodes are on the opposite sides of an LED die—a vertical LED structure. A vertical LED structure generally costs less to make because it avoids some lithography/etching/cleaning steps in device fabrication processes. However, because sapphire is electrically insulating, GaN/InGaN-thin-film-based LEDs on sapphire substrates are made by placing the electrodes onto the same side of LED dies. For GaN/InGaN-thin-film-based LEDs on conducting SiC substrates, a vertical LED structure is usually employed. However, SiC is a strong absorber of visible light, which typically adversely affects light extraction from the LEDs. A DS GaN composite wafer with a GaN thick film on a sapphire substrate can enable a vertical LED device structure. For example, when a DS GaN composite wafer with a GaN layer of about 150 μm or more in thickness with an n-type conductivity (or a p-type conductivity) is used as a substrate in epitaxy of HB-LED structures, the DS GaN composite wafer with LED layers can be thinned from the back side so that the GaN layer and the sapphire substrate are completely removed. Thus, a thin device wafer with LED layers grown on a conducting GaN layer is produced. The LED layers can be about 120 μm in thickness, although the present invention is not limited in this regard as the LED layers can be thinner or thicker. The thin LED device wafer 10 is shown in FIG. 6A as having a substrate 12 having a thickness Tₛ of about 330 μm and crystal layers 14 having thicknesses T_{c} of about 150 μm, one of which defines a polished epi-ready surface (14a) (n-type GaN) and the other of which defines a ground surface (14b) (p-type GaN). This wafer 10 can then be fabricated into an LED with a vertical structure, which is schematically shown in FIG. 6B and hereinafter referred to as “vertical device 50.” In the vertical device 50, metal contacts 55 are located on the polished epi-ready surface 14a (n-type GaN) and the ground surface 14b (p-type GaN) with a GaN/InGaN MQW 17 located therebetween. The present invention is not limited to the MQW 17 being GaN/InGaN, however, as other materials may be used. In any case, being able to adopt a vertical LED structure simplifies the LED fabrication process, and thus reduces LED fabrication cost. An LED on a GaN thick film with a high thermal conductivity, instead of being on a sapphire substrate with a very low thermal conductivity, also exhibits more desirable performance because of an increased ability to dissipate heat from the LED.

In summary, the three attributes of a DS GaN composite wafer (i.e. a low wafer bow, a low dislocation density, and an ability to enable a vertical device structure) are indicative of the fabrication of high-performance III-nitride LEDs at low cost. Although the benefits of using a DS composite wafer discussed thus far mostly use GaN-based LED devices as examples, these benefits are similar for other III-nitride-based devices, including blue and green laser diodes (LDs), high frequency devices (e.g. high electron mobility transistors, also known as HEMTs), high-power switching devices (e.g. Schottky diodes, PIN diodes, MESFETs), UV detectors, photovoltaic devices (solar cells), etc.

In another way to make a DS composite wafer of the present invention, a DS composite wafer can be made with an insulating III-nitride layer disposed on each side of a substrate. One example is a DS GaN composite wafer with a Fe-doped semi-insulating GaN layer on one side or both sides of a sapphire substrate. Another example is a DS AlN composite substrate on a sapphire substrate (i.e. AlN/sapphire/AlN), where the AlN is inherently electrically insulating. A DS composite wafer with an insulating or a semi-insulating III-nitride layer is employed as a substrate for fabrication of high-frequency (RF) devices, such as high electron mobility transistors (HEMTs) for microwave applications.

A DS composite wafer can also be made in such way that it contains a device structure in a III-nitride layer on one side or on both sides of a substrate using a MOCVD technique. One can choose to use one device layer or both device layers for fabrication of devices. One example of using both device layers for device fabrication is to make a III-nitride-based tandem solar cell.

Another way to use a DS composite wafer is that one can further fabricate a DS composite wafer with two thick III-nitride layers (preferably 250 μm or thicker) produced in an HVPE growth into a freestanding III-nitride wafer by grinding away one of one III-nitride layer and the sapphire substrate. Because a DS composite wafer can maintain a very low or essentially no bow before the grind process, a freestanding III-nitride wafer made this way has a low mechanical bow or essentially no mechanical bow. Also, one can further fabricate a DS composite wafer with two thick III-nitride layers (preferably 250 μm or thicker) produced in a HVPE growth into two freestanding III-nitride wafers by first separating the two thick III-nitride layers and then grinding away the portion of the substrate attached to each of the two III-nitride layers. Two freestanding III-nitride wafers made this way both have a low mechanical bow or essentially no mechanical bow. An example of such freestanding III nitride wafers is a freestanding GaN wafer produced using a DS GaN composite wafer with a thick GaN layer (preferably 250 μm or thicker) on each of the two sides of a sapphire substrate by grinding away one of the thick GaN layer and the sapphire substrate. The freestanding GaN wafers made this way have a low mechanical bow or essentially no mechanical bow as well as a low dislocation density.

Although this invention has been shown and described with respect to the detailed embodiments thereof, it will be understood by those of skill in the art that various changes may be made and equivalents may be substituted for elements thereof without departing from the scope of the invention. In addition, modifications may be made to adapt a particular situation or material to the teachings of the invention without departing from the essential scope thereof. Therefore, it is intended that the invention not be limited to the particular embodiments disclosed in the above detailed description, but that the invention will include all embodiments falling within the scope of the appended claims.

What is claimed is:

1. A composite wafer comprising:
a single crystal substrate having a first side and an opposing second side;
a first III-nitride single crystal layer disposed on the first side of the single crystal substrate and being defined by a thickness;
a second III-nitride single crystal layer disposed on the second side of the single crystal substrate and being defined by a thickness;
wherein the thickness of the first III-nitride single crystal layer is substantially the same as the thickness of the thickness of the second III-nitride single crystal layer.

2. The composite wafer of claim 1, wherein the single crystal substrate comprises sapphire.

3. The composite wafer of claim 1, wherein the single crystal substrate is selected from the group of materials consisting of SiC, ZnO, Si, GaAs, Ge, SiO₂, and LiAlO₃.

4. The composite wafer of claim 1, wherein the first III-nitride single crystal layer and the second III-nitride single crystal layer each comprise one or more materials selected from the group consisting of GaN, AlN, InN, InₓGa₁₋ₓ N (0<x<1), AlₓGa₁₋ₓ N (0<x<1) InₓAl₁₋ₓ N (0<x<1), InₓGa_{y}Al_{1-x-y}N (0<x<1 and 0<y<1).

5. The composite wafer of claim 1, wherein the thickness of the first III-nitride single crystal layer and the thickness of the second III-nitride single crystal layer are each about 1-1000 μm.

6. The composite wafer of claim 1, wherein a distortion height of the composite wafer is less than about 0.5 mm.

7. The composite wafer of claim 1, wherein a distortion height of the composite wafer is less than about 0.2 mm.

8. The composite wafer of claim 1, wherein the first III-nitride single crystal layer has a dislocation density up to about 5×10⁸ cm⁻².

9. The composite wafer of claim 1, wherein the first III-nitride single crystal layer has a dislocation density up to about 1×10⁶ cm⁻².

10. The composite wafer of claim 1, wherein the first III-nitride single crystal layer comprises an n-type semiconductor with an electrical resistivity of about 0.0001 ohm-cm to about 10.0 ohm-cm.

11. The composite wafer of claim 1, wherein the first III-nitride single crystal layer comprises a p-type semiconductor with an electrical resistivity of about 0.0001 ohm-cm to about 10.0 ohm-cm.

12. The composite wafer of claim 1, wherein the first III-nitride single crystal layer is semi-insulating with an electrical resistivity greater than about 1,000 ohm-cm.

13. The composite wafer of claim 1, wherein the first III-nitride single crystal layer is semi-insulating with an electrical resistivity greater than about 100,000 ohm-cm.

14. The composite wafer of claim 1, wherein the first III-nitride single crystal layer has an as-grown surface with an RMS surface roughness of up to about 2.0 nm.

15. The composite wafer of claim 1, wherein the first III-nitride single crystal layer has an as-grown surface with an RMS surface roughness of up to about 0.5 nm.

16. The composite wafer of claim 1, wherein the first III-nitride single crystal layer has a polished surface with an RMS surface roughness of up to about 2.0 nm.

17. The composite wafer of claim 1, wherein the first III-nitride single crystal layer has a polished surface with an RMS surface roughness of up to about 0.5 nm.

18. The composite wafer of claim 1, wherein the first III-nitride single crystal layer and the second III-nitride single crystal layer are disposed on the single crystal substrate using an epitaxial growth process.

19. The composite wafer of claim 18, wherein the first III-nitride single crystal layer and the second III-nitride single crystal layer comprise a semiconductor device structure that can be fabricated into one or more semiconductor devices selected from the group consisting of light emitting diodes, laser diodes, RF devices, high electron mobility transistors, high power switching devices, Schottky diodes, PIN diodes, UV detectors, photo-voltaic devices, solar cells, and combinations of the foregoing devices.

20. The composite wafer of claim 1, wherein the first III-nitride single crystal layer comprises a semiconductor device structure that can be fabricated into one or more semiconductor devices selected from the group consisting of light emitting diodes, laser diodes, RF devices, high electron mobility transistors, high power switching devices, Schottky diodes, PIN diodes, UV detectors, photo-voltaic devices, solar cells, and combinations of the foregoing devices.

21. The composite wafer of claim 1, wherein the composite wafer is fabricated into a freestanding III-nitride wafer.

22. The composite wafer of claim 21, wherein the freestanding III-nitride wafer has a distortion height of up to about 0.5 mm.

23. The composite wafer of claim 1, wherein the composite wafer is fabricated using a crystal growth method selected from the group consisting of a MOCVD technique, an HVPE technique, and combinations of the foregoing techniques.
